(19) United States
(12) Patent Application Publication
(10) Pub. No.: US 2012/0125702 A1
(43) Pub. Date: May 24, 2012

(54) Battery Pack, an Electric Vehicle and a Method

(76) Inventor: Thomas Bergfjord, Uppsala (SE)

(21) Appl. No.: 13/388,791

(22) PCT Filed: Aug. 2, 2010
(86) PCT No.: PCT/SE10/50873

§ 371 Date: Feb. 3, 2012

(51) Int. Cl. H02J 7/00; B60L 11/18; H05K 13/00; H01M 2/02; H01M 2/10

(52) U.S. Cl. 180/65.1; 320/104; 429/122; 429/163; 29/592.1

(57) ABSTRACT

The present invention relates to a battery pack (11, 35a, 35b, 55), an electric driven vehicle comprising a battery pack, an electric driven vehicle comprising a mounting space (53) for accommodating a battery pack, and a method. At least a part of the battery pack (11, 35a, 35b, 55) is mountable underneath a lower floor portion (19) of a passenger compartment (13) of the vehicle.

### TECHNICAL FIELD

The present invention relates to a battery pack, an electric vehicle comprising a battery pack, an electric vehicle comprising a mounting space for accommodating a battery pack, and a method.

### PRIOR ART

Electric vehicles comprising electric engines for propulsion of the vehicles are known in the art since mid 19th century. Electric vehicles experienced a peak at the beginning of the 20th century, after which they were outcompeted by the combustion engine, mostly due to the increased range provided by the energy density in fossil fuels.

Even today one of the main problems for electric vehicles is the limited range due to the small energy capacity of the batteries. One known method of providing electric energy is to provide a very large number of small batteries, up to about 6800 batteries, located within the engine compartment and the luggage space of the vehicle. Another known method comprises providing vacuum sealed and heated batteries to increase their capacity. It is also known to provide batteries in a space provided under the rear seats, and in a space otherwise provided for the drive shaft in a combustion vehicle, such as shown in FR2801539.

### SUMMARY OF THE INVENTION

One object of the present invention is to alleviate the problems of a short range for electric vehicles.

This object is achieved with the battery pack according to claim 1, the vehicles according to claims 7 and 16, and the method according to claim 17.

By mounting at least a part of a battery pack containing at least a part of one battery cell underneath a lower floor portion of the passenger compartment of the vehicle a new storage area for batteries is achieved, which hitherto has not been used for the storage of batteries. Since the area underneath the passenger compartment of the vehicle is usually very large, the usable volume for storage underneath the vehicle is also large, even though the available height may be limited. Hence a hitherto unused and large volume underneath the vehicle may be utilised for storing batteries, so that the number of batteries may be increased in comparison with the prior art. Hence the electricity storage capacity and thus the range of the vehicle may be increased considerably. Alternatively, space may be freed elsewhere in the vehicle for providing additional space for passengers, luggage or other components within the vehicle.

Preferably the vehicle is designed with a sufficiently high ground clearance to accommodate the batteries underneath the vehicle. Hence there is less risk that the underside of the vehicle impact with the ground or with objects lying on the ground. In case of using a vehicle originally designed with low ground clearance, the suspension may be modified to raise the vehicle in order to retain at least some of the original ground clearance for the vehicle.

The vehicle is preferably a land-based, motor driven vehicle. Preferably, the vehicle is a road-based vehicle for use on the public road network. Preferably, the vehicle is a large, land-based, road-bound, motor driven vehicle, such as a car, lorry, or bus. Preferably, the vehicle is a passenger car. The invention may also be applicable for other types of vehicles, such as boats.

Preferably, battery packs other than the battery pack underneath the passenger compartment may also be provided at known storage locations, such as in the engine compartment at the front of a vehicle, under the back seat in the passenger compartment, in a space under the luggage boot, and in the space previously occupied by the drive shaft and/or fuel tank for a conventional combustion vehicle. Thus the number of batteries provided in the vehicle may in fact almost be doubled relative to the number of batteries provided in the prior art. Hence the range of a vehicle may also almost be doubled, which at least to some degree alleviates the problem of a short range.

A battery pack may comprise one or more battery cells, preferably at least two complete batteries having two or more battery cells each, and more preferably at least five, most preferably at least 25 batteries. Preferably the battery pack also comprises less than 10 000 batteries for smaller vehicles, and less than 30 000 batteries for large vehicles such as a truck or boat. The batteries in the battery pack are preferably electrically interconnected, for example in series and/or in parallel or in any combination thereof. The batteries in the battery pack are preferably also grouped together so as to form a common body. Preferably, the batteries in a battery pack are positioned adjacent to each other, preferably abutting against each other. Preferably, the batteries are also mechanically connected with each other, so as to form a single unit, which may be movable in one piece. The battery pack may also comprise a housing and/or an inner support for holding the batteries together.

In an alternative embodiment the battery pack may instead comprise a collection of batteries grouped together so as to form a common body, even if the batteries are not mechanically rigidly connected. In yet another alternative embodiment the batteries may also be positioned spaced apart. The battery pack may also be housed inside a frame or bodywork forming the underside of the vehicle. The battery pack may also be an integrated part of the frame or bodywork, wherein the frame or bodywork forms the housing for the battery pack. The battery pack may also constitute at least part of the underside, so that the battery pack will affect the ground clearance of the vehicle as little as possible.

The passenger compartment may comprise one or more sidewalls for protecting the driver and/or passengers, and may also comprise one or more doors for simplifying entering and exit from the passenger compartment. The meaning of the term passenger compartment is here considered to also encompass a compartment for the driver of the vehicle. A motorcycle however, is ordinarily not considered to have a passenger compartment. The underside of the floor portion of the passenger compartment is traditionally one of the lowest parts of a vehicle, in particular of a land-based vehicle. Preferably, the at least one part of the at least one battery pack is mounted underneath the lower and/or lowest part or parts of the passenger compartment. Preferably, the at least one part of a battery pack containing a battery cell is also mounted underneath a floor portion of the passenger compartment adapted for allowing a driver and/or passengers to place their feet upon the floor portion. Preferably, the at least one part of a battery pack is also mounted underneath a floor portion of the passenger compartment adapted for placing a front seat on the floor portion. In one embodiment, the term floor portion of the passenger compartment is considered not to include the area directly beneath a seat, which is usually located at a higher position slightly above the floor portion of the passenger compartment, nor is the luggage compartment intended to be included. Nor are any parts of the floor which are raised relative to the lower parts, such as the channel formerly formed to contain a drive shaft, considered to be a part of the lower floor portion.

According to one embodiment the part of the battery pack mountable underneath the floor portion of the passenger compartment has a maximum thickness, as measured in the vertical direction when mounted, which is less than or equal to 18 cm. Thus it is ensured that the battery pack does not decrease ground clearance to any large degree, or that the vehicles suspension does not need to be raised too much, which otherwise might affect the road holding properties of the vehicle. In another embodiment the thickness of the battery pack mountable underneath the floor portion of the passenger compartment is less than or equal to 15 cm, in yet another embodiment less than or equal to 12 cm, and in yet another, preferred embodiment less than or equal to 10 cm, or, in another embodiment, less than or equal to 8 cm. Preferably the thickness of the battery pack is furthermore greater than or equal to 1 cm, preferably 2 cm, and more preferably 4 cm, so that the volume of the batteries positioned underneath the passenger compartment is large so as to be able to contain more energy. The thickness of the part of the battery pack containing at least one battery cell mounted underneath the passenger compartment is preferably measured in absolute terms, from the bottom surface to the top surface of the battery pack, and for each point of the battery pack, wherein the thickness limit should be met for at least a major part of the battery pack. In an alternative embodiment the thickness may be measured as an average thickness. In case the battery pack is joined with other battery packs, such as the battery packs under the rear seat, the thickness need not be met for these joined parts. Preferably however, the battery pack underneath the lower floor portion and/or along the underside of the vehicle forms a battery pack separate from batteries located above the floor portion of the passenger compartment.

According to one embodiment the part of the battery pack mountable underneath the floor portion of the passenger compartment extends laterally along the underside of the vehicle when mounted and has a horizontal area which is greater than or equal to 400 cm². Preferably the horizontal area is greater than or equal to 600 cm², more preferably greater than or equal to 800 cm², and most preferably greater than or equal to 10 000 cm². The horizontal area is also preferably smaller than the area of the underside of the vehicle so as not to extend outside the vehicle. In case of a car, the largest area may be less than or equal to 4 m², or, in case of a boat, less than or equal to 20 m².

The area of the battery pack is here considered to be the area in the horizontal direction when the battery is mounted for actual use in a vehicle. The lateral dimension of the battery pack is similarly considered to encompass the horizontal dimensions of the battery pack when the battery pack is in use. The width is considered the shortest side of the battery pack in a horizontal direction when the battery is used in a vehicle, and the length is considered the longest side of the battery pack in a horizontal direction when the battery is used in a vehicle.

According to one embodiment the one or more battery packs is/are designed to occupy at least 50% of the underside area underneath the floor portion of the passenger compartment. More preferably the one or more battery packs is/are designed to occupy at least 70% of the underside area underneath the floor of the passenger compartment. Preferably the one or more battery packs is/are designed to occupy less than 95% of the underside area underneath the floor of the passenger compartment. Hence it is ensured that a large portion of the area underneath the passenger compartment is used for accommodating batteries.

According to one embodiment the one or more battery packs is/are also designed to occupy at least 50% of the underside area of the vehicle, preferably at least 70% of the underside area of the vehicle. Preferably the one or more battery packs is/are also designed to occupy less than 95% of the underside of the vehicle.

According to one embodiment at least a portion of the battery pack is shaped as a thin, box having a low thickness relative to its width and/or length, and is designed to be mounted in connection with an underside of the vehicle, so that the thin, box-shaped portion extends along at least a part of the underside. Preferably the thin, box-shaped portion also extends laterally and in parallel with the underside. Preferably the thin, box-shaped portion of the battery pack is also mounted closely onto the underside. By providing a thin, box-shaped battery pack underneath the vehicle, the arrangement of the battery pack onto the underside of the vehicle is simplified. Further, by providing a battery pack comprising a thin, box-shaped portion the ground clearance is affected as little as possible, alternatively, the vehicle may be lowered, so as to achieve better road holding performance. Preferably, the thin, box-shaped portion comprises at least 40% of the area of the battery pack, more preferably at least 50% of the area of the battery pack, and most preferably at least 70% of the area of the battery pack.

With the expression that the battery pack is arranged in connection with the underside is intended that the battery pack may be mounted in level with a frame forming a lowermost supporting structure of the vehicle, mounted at a small distance from the underside surface of the vehicle, mounted flush with the underside of the vehicle, and/or mounted directly onto an outer surface of the underside of the vehicle. The battery pack may also be covered with a protective cover arranged on its underside, without departing from the scope of the invention.

The thin, box-shaped battery pack preferably comprises two opposing surfaces constituting a top surface and a bottom surface of the box-shaped portion of the battery pack, and which forms the two largest surfaces of the thin, box-shaped portion. In one embodiment the thickness of the box-shaped portions of the battery pack may be given by the perpendicular distance between the two opposing surfaces, either in an absolute and/or in an average sense. The two surfaces may be discontinuous surfaces, but are preferably planar. The downward facing surface of the box-shaped battery pack may be flat, so as to decrease drag, but it may also be curved, preferably convex shaped, so as to create an under pressure below a land-based vehicle to press the vehicle against the ground. Also, the two surfaces are preferably parallel with each other for at least 50%, preferably at least 70%, of their area. However, if the surfaces are broken, the surfaces may still be considered to be parallel in case the average surface shapes are parallel to each other. Preferably, the battery pack may also be plate-shaped, having a flat top surface and a flat under surface.

According to one embodiment the thin box-shaped portion of the battery pack extends laterally along the underside of the vehicle when mounted and has a horizontal area which is greater than or equal to 400 cm². Preferably the horizontal area is greater than or equal to 600 cm², more preferably greater than or equal to 800 cm², and most preferably greater than or equal to 10 000 cm². The horizontal area is also preferably smaller than the area of the underside of the vehicle, so as not to extend outside the vehicle. In case of a car, the largest area may be less than or equal to 6 m², or, in case of a boat, less than or equal to 40 m².

According to one embodiment of the invention at least a part of the thin box-shaped portion of the at least one battery pack is mounted underneath a floor portion of the passenger compartment of the vehicle. Preferably the thin box-shaped portion or portions of the one or more battery packs is/are designed to occupy at least 50% of the underside area underneath the floor of the passenger compartment. More preferably the box-shaped portion or portions of the one or more battery packs is/are designed to occupy at least 70% of the underside area underneath the floor of the passenger compartment. By providing a thin, box-shaped battery pack underneath the passenger compartment, the arrangement of the battery pack onto the underside of the vehicle is simplified. Preferably the box-shaped portion or portions of the one or more battery packs is/are designed to occupy less than 95% of the underside area underneath the floor of the passenger compartment. Thus there is room for the lower edges of the vehicle bodywork, fastening members or similar. If the vehicle is an aircraft or a boat the box-shaped battery pack may also be arranged to cover the entire hulls of the vehicles.

According to one embodiment of the invention at least one portion of the at least one battery pack is arranged to extend both underneath the floor of the passenger compartment and underneath at least one other part of the vehicle, other than the floor of the passenger compartment. Hence the battery pack is not limited to be arranged underneath the floor portion of the passenger compartment but may also be arranged underneath other parts. Thus an even larger battery pack may be used underneath the vehicle.

According to one embodiment of the invention the vehicle comprises a downward facing surface on the underside of the vehicle, which downward facing surface is planar. A battery and hence a battery pack is easy to manufacture with a planar surface oriented in a specific direction. By letting the underside of the vehicle and the downward facing surface of the underside be constituted by either a frame housing such a battery pack, and/or by letting at least a part of the downward facing surface be constituted by a planar surface of such a battery pack, it is easy to make the downward facing surface planar. A planar downward facing surface in turn decreases the drag coefficient between the vehicle and the air, which may decrease energy consumption when driving the vehicle.

According to one embodiment of the invention at least a part of the downward facing surface is constituted by at least a surface section of the thin box-shaped battery pack. The batteries may then be provided with a durable and impact resistant wall facing downwards. According to another embodiment the downward facing surface may instead be constituted by a cover covering the battery pack. The cover may be a part of the battery pack, or the cover may be part of a frame housing the battery pack.

According to one embodiment of the method according to the invention a first battery pack having a low state of charge is removed from the underside of the vehicle, and a second, similar battery pack having a higher state of charge is then attached in connection with the underside of the vehicle to replace the first battery pack. Hence, the energy of the vehicle may quickly be replenished. Preferably, a third, permanent battery pack associated with the vehicle is recharged with energy from the second battery pack. Hence, permanent, non-detachable battery packs may easily and quickly be provided with more energy by changing the detachable battery pack or packs, without need to recharge the permanent, non-replaceable battery packs through an external energy source, which usually only can be done while the vehicle is standing still.

According to one embodiment the vehicle comprises a single battery pack arranged in connection with the underside of the vehicle, wherein the battery pack is at least 1 m wide and 1.4 m long. Preferably the battery pack extends along the entire underside of the vehicle. Alternatively, the battery pack is smaller than 1.3 m in both width and length, and the vehicle comprises a plurality of mounting spaces for, and/or containing such battery packs in connection with the underside of the vehicle. Hence, each battery pack will be light and limited in size, making them easier to handle. Preferably the battery pack or packs is/are plate-shaped, comprising a flat top surface parallel with a flat under surface. Preferably the battery pack is also separate from any batteries located above the lower floor portion of the passenger compartment.

According to one embodiment the vehicle is a land-based, road-bound vehicle comprising an underside surface facing the road which is convex shaped. When the vehicle is in motion an airstream is flowing in the area underneath the vehicle and above the road. Due to the convex shape of the underside surface the cross-sectional area formed underneath the vehicle changes with the height of the underside surface, from a smaller cross-section towards a larger cross-section. The airstream will thus experience a lower pressure under the vehicle, which in turn generates a force acting to press the vehicle towards the road, giving the vehicle a better adherence to the road and better road characteristics.

### BRIEF DESCRIPTION OF THE ATTACHED DRAWINGS

The invention is now to be described as a number of non-limiting examples of the invention with reference to the attached drawings.

FIG. 1a shows a side view of a vehicle provided with a battery pack according to a first example of the invention.

FIG. 1b shows an underside view of the vehicle shown in FIG. 1a.

FIG. 2a shows one example of a box-shaped battery pack according to one example of the invention.

FIG. 2a shows another example of a box-shaped battery pack according to the invention.

FIG. 3 shows an underside view of a vehicle provided with a battery pack according to a second example of the invention.

FIG. 4 shows a method according to one example of the invention.

FIG. 5 shows yet another view of a vehicle according to the invention.

### DETAILED DESCRIPTION

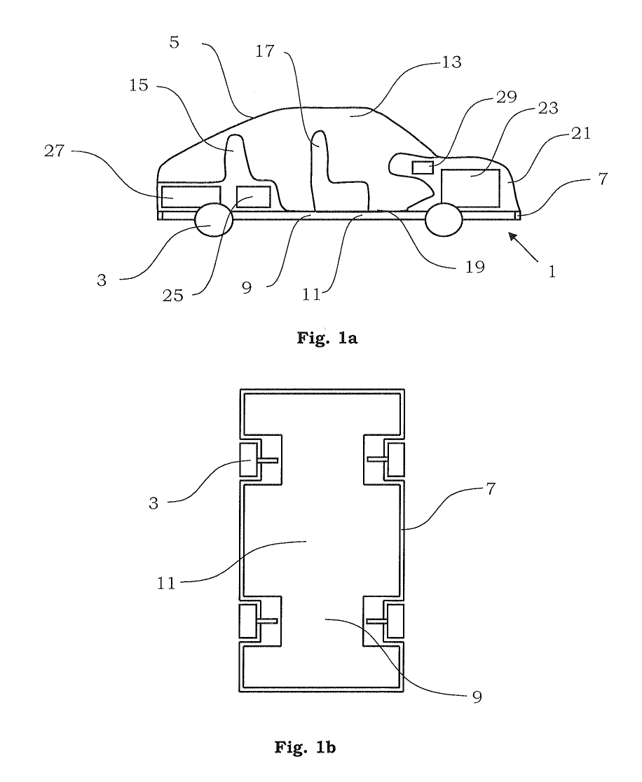

In FIG. 1a-b an electric motor driven vehicle 1 according to one example of the invention is shown. The vehicle may be any kind of electric motor driven vehicle, like a sea-based vehicle such as a boat, or an aerial vehicle, such as an airplane. Preferably, however, the vehicle is a land-based, electric motor driven vehicle, preferably a road-bound vehicle, and preferably a large vehicle having three or more wheels, such as an automobile, bus, or lorry. In this example the vehicle 1 is a land-based passenger car comprising four wheels 3 intended to make contact with the ground for driving the vehicle. The electric vehicle also comprises one or more electric motors (not shown) connected with the wheels for providing propulsion to the vehicle.

The vehicle 1 further comprises a bodywork 5 forming a protective shell around the vehicle and defining the shape of the vehicle. The vehicle further comprises a frame 7, forming an inner, and/or lower structure for supporting the vehicle. Such a frame may be named a chassis in case of cars, but may be named differently for other types of vehicles. The bodywork 5 and/or the frame 7 are further shaped to comprise an underside 9, forming the bottom of the vehicle and having a downward facing surface. Depending on the type and design of the vehicle the underside may be formed by either or both of the bodywork and the frame.

The vehicle further comprises a battery pack 11 comprising at least one battery, preferably a plurality of interconnected batteries, for providing electric energy to the at least one electric motor, for propulsion of the vehicle. The vehicle 1 is further provided with a passenger compartment 13 for accommodating living beings, such as a driver and possible passengers in the vehicle. The passenger compartment may be provided with a back seat 15 and one or more movable seats 17, in this example a front seat. The passenger compartment further comprises a floor portion 19 forming the lower, or lowest, parts of the passenger compartment. The passenger compartment also comprises sidewalls (not shown) to protect the driver and/or passengers. In this example the floor portion is adapted for supporting any movable seats and for receiving the feet of the driver and any passengers. Neither the back seat, the rear storage area, nor any raised portions, such as the channel formerly adapted for housing a drive shaft, are here considered to be included in the definition of the passenger compartment floor portion.

According to this example of the invention at least a part of the battery pack 11 containing at least one battery cell is mounted underneath the lower floor portion 19 of the passenger compartment 13 of the vehicle. Hence at least one battery cell is positioned underneath the lower floor portion or portions of the passenger compartment. The area under the floor portion 19 of the passenger compartment 13 may constitute about one third of the total area of the underside of the vehicle. Hence a large volume previously considered unusable may be used for storage of a large battery pack, effectively increasing the range of the vehicle.

In order to accommodate the battery pack 11 underneath the vehicle the suspension may be modified to raise the vehicle slightly from the ground. In this example the vehicle is raised so that the floor of the passenger compartment is positioned 8 cm higher than if the battery pack 11 located on the underside had not been intended to be provided.

In this example at least a portion of, in this case the entire, battery pack is shaped as a thin box having a low thickness relative to its width and length. The battery pack 11 is designed to be mounted in connection with the underside 9 of the vehicle, so that the thin, box-shaped battery pack 11 extends laterally, parallel with, and along the underside 9. In this example the battery pack is directly and tightly attachable onto the underside 9 of the vehicle 1.

In this example the battery pack 11 is further designed to extend beyond the area of the floor portion 19 of the passenger compartment, so as to extend also underneath other parts of the vehicle 1. In this example the battery pack 11 is designed to extend towards the front of the vehicle 1, and underneath a frontal chamber 21 of the vehicle comprising the engine compartment housing the at least one electric motor for propulsion of the vehicle, and also one or more additional battery packs 23, having a traditional shape. The battery pack 11 is further arranged to extend backwards beneath the back seat, and further back towards the rear, storage compartment. The vehicle 1 may comprise additional battery packs 25 and 27 underneath the back seat and the storage compartment, respectively, and located above the thin, box- shaped battery pack 11. Hence, in this example, the battery pack 11 is positioned underneath the other, traditional battery packs 23, 25 and 27.

In this example the box-shaped battery pack 11 and the battery packs 23, 25 and 27 are designed to form separate battery packs, but in another example the box-shaped battery pack 11 and one or more of the battery packs 23, 25 and 27 may be merged to form a joint, single battery pack. In the latter case the merged battery pack would still comprise a thin, box-shaped portion having a low thickness relative to the width and length of that portion, as represented by battery pack 11.

In this example, as is more easily seen in FIG. 1b, the battery pack 11 is designed to occupy at least 50% of the underside area underneath the floor 19 of the passenger compartment. In this example the battery pack 11 is designed to occupy at least 70%, and preferably at least 85%, of the underside area underneath the floor 19 of the passenger compartment. Furthermore the battery pack 11 is designed to occupy at least 50% of the underside area of the vehicle as a whole. In this example the battery pack 11 is designed to occupy at least 70%, preferably at least 85%, of the underside area of the vehicle 1 as a whole. Hence a very large portion of the area underneath the vehicle is utilised for storage of the battery pack 11. Preferably the battery pack 11 is designed to cover, as far as practical, the entire area of the underside 9 surface of the vehicle.

The battery pack 11 is further formed as a separate box having a low thickness and containing the batteries. In this example the battery pack is formed as a single, connected unit, comprising its own housing and/or inner frame for holding the batteries together. Alternatively, the batteries contained in the battery pack 11 could instead be mounted, for example one by one, directly into a frame 7 containing a mounting space for the batteries. Hence the battery pack would be assembled and completed only after being mounted into the vehicle.

The battery pack and/or the vehicle may be provided with a protective cover for protecting the batteries from impact with the ground or objects lying on the ground. The protective cover may provide a downward facing surface which is substantially planar, to decrease drag.

The vehicle 1 is preferably a wide and long vehicle, having an underside 9 with a width of at least 1.4 m and a length of at least 1.8 m. Hence it is ensured that the underside has a large area for providing space for the battery pack 11. In this example the battery pack is arranged to extend laterally in parallel with and along the length and width of the underside 9.

In this example, the thickness of the box-shaped portion mounted underneath the floor portion of the passenger compartment is less than or equal to 18 cm. In this example the thickness is less than or equal to 15 cm, in this example less than or equal to 12 cm, in this example less than or equal to 10 cm. In this example, the thickness of the box-shaped portion of the battery pack is also greater than 2 cm. In this example the thickness is 8 cm. In this example the horizontal area of the box-shaped portion mounted underneath the floor portion of the passenger compartment is greater than or equal to 400 cm², in this example greater than or equal to 600 cm², in this example greater than or equal to 800 cm², in this example greater than or equal to 10 000 cm². The horizontal area is also smaller than the area of the underside of the vehicle, so as not to extend outside the vehicle. Preferably, the battery pack 11 is at least 50 cm wide and at least 1.2 m long.

The battery pack 11 is furthermore easily detachable from underneath the vehicle. The vehicle is further designed so that the battery pack is easily replaced with another, similar battery pack. Hence, when the energy in the battery pack 11 becomes low, the battery pack 11 may be replaced with another battery pack having a higher charge, or, preferably, being fully charged. Thus a simple and fast recharge of the vehicle may be performed by simply replacing the battery pack 11. Thus, the detachable battery pack may be replaced on a regular basis when fully or partially depleted.

The battery pack 11 may be replaced automatically by a robot at a refuelling station, such as for example with the system conceived by Better Place®. Preferably, the battery pack 11 is replaced by detaching the battery downwardly.

The battery packs 23, 25 and 27 are permanent battery packs, and are thus designed to remain fixed with the vehicle. The permanent battery packs 23, 25, 27 are designed not to be replaced when depleted, but to be recharged with a recharging current. For this purpose, the vehicle comprises a battery charger 29, arranged to manage the recharge of the batteries 23, 25, 27. The recharge current may be supplied from an external power source, or the recharge current may be withdrawn from a highly charged battery pack 11. Hence by replacing a battery pack 11 with low charge with a new battery pack with a higher charge, the charge of the permanent battery packs 23, 25, 27 may also be indirectly replenished.

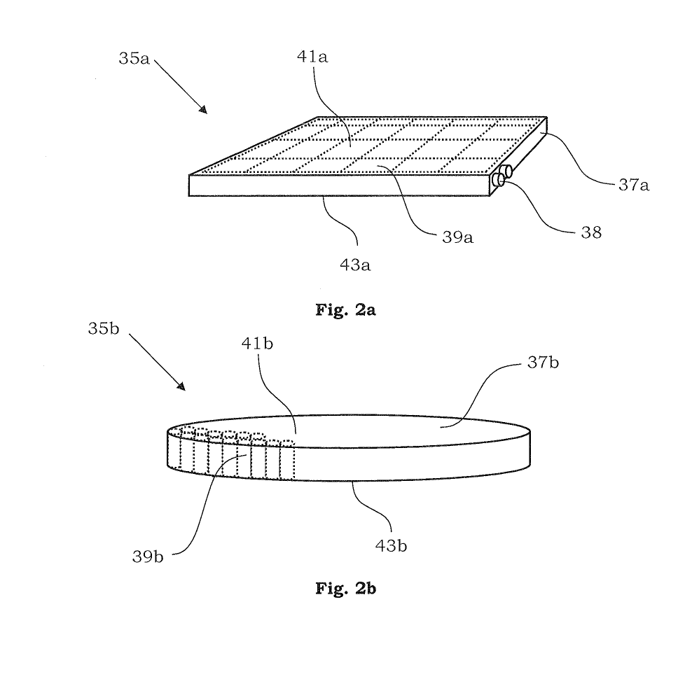

In FIG. 2a-b two examples of the design of battery packs 35a, 35b are shown. The battery packs 35a, 35b, each comprise a housing 37a, 37b, for protecting and holding a plurality of batteries 39a, 39b together, and defining the outside surfaces of the battery packs. The batteries 39a, 39b are indicated by dashed lines in the FIGS. 2a-b. In an alternative embodiment the battery packs may comprise an inner support instead of, or in combination with, the housings 37a, 37b, or may be held together by external elements provided by the vehicle itself. Also, the battery pack housing 37a, 37b, may act as part of the frame for the vehicle and to support the vehicle. As shown in FIG. 2a the battery pack may also be provided with contacts 38 for allowing electrical connection of the batteries in the battery pack to the vehicle.

In this example both battery packs 35a, 35b are box-shaped and thin, wherein the thicknesses of the battery packs are small in comparison to their areas or lateral dimensions. The thicknesses of the battery packs are here considered to be the height of the battery packs in the vertical direction when the battery packs are mounted for use in a vehicle. The lateral dimensions, and the areas, of the battery packs are here considered the dimensions of the battery packs in a horizontal direction when the battery packs are in use in a vehicle.

In this example the box-shaped battery-packs 35a, 35b are also substantially flat so that the battery packs may easily be arranged on the flat underside of a car, but in another example a battery pack may be curved to follow for example the curved hull of a boat, or to act on surrounding air.

The battery packs 37a, 37b are further shaped with two opposing surfaces 41a, 43a; 41b, 43b defining the top surface 41a, 41b and the bottom surface 43a, 43b of the battery packs, respectively. In this example the bottom surfaces 43a, 43b are planar, wherein it is easier to form a planar downward facing surface of the vehicle. The top surfaces 41a, 41b are also planar, and the two opposing surfaces are substantially parallel with each other and arranged at an equal distance from each other. In another example the top and bottom surfaces could be discontinuous. However, the average extension of the bottom and top surfaces are still preferably flat and parallel with each other.

In FIG. 2a the shape of the box-shaped battery pack 35a is rectangular, wherein the battery pack 35a has a width and a length defining the lateral dimension of the battery pack. The width is considered the shortest side of the battery pack in a horizontal direction when the battery is used in a vehicle, and the length is considered the longest side of the battery pack in a horizontal direction when the battery is used in a vehicle.

In this example the thickness of the battery pack 35a is 8 cm. In this example the length of the battery pack is greater than 40 cm, preferably greater than 60 cm. In this example the length of the battery pack is also less than 200 cm. In this example the length of the battery pack 35a is 120 cm. In this example the width of the battery pack is greater than 10 cm, preferably greater than 20 cm. In this example the width of the battery pack is less than 120 cm. In this example the width of the battery pack 35a is 100 cm. In this example the area of the box-shaped portion of the battery pack is thus greater than or equal to 400 cm², in this example equal to 12000 cm². The horizontal area is also less than or equal to 6 m².

The batteries 39a are also rectangular and are arranged adjacent, next to each other. The batteries are arranged with their shortest side in the thickness direction to decrease the height of the battery pack. However, depending on for example the relative size of the batteries and the vehicle, the batteries may be oriented differently.

In FIG. 2b the shape of the battery pack 35b is circular, wherein the battery pack 35b has a radius defining the lateral dimension of the battery pack. In this example the radius is less than 1 m, preferably less than 0.6 m. In this example the radius is greater than 0.5 dm, preferably greater than 2 dm. In this example the radius is 0.5 m. In this example the area of the box-shaped portion of the battery pack is thus equal to 7850 cm². The batteries 39b inside the battery pack 35b are in this example circular cylindrical, and are arranged as closely packed as allowed by their shape. The batteries are in this example oriented with their lengths in the thickness direction of the battery pack.

Thus two basic shapes are shown which could be used for the battery packs according to the invention. However, other shapes may also be useful depending on the shape, size and form of the vehicle to which the battery packs are to be attached.

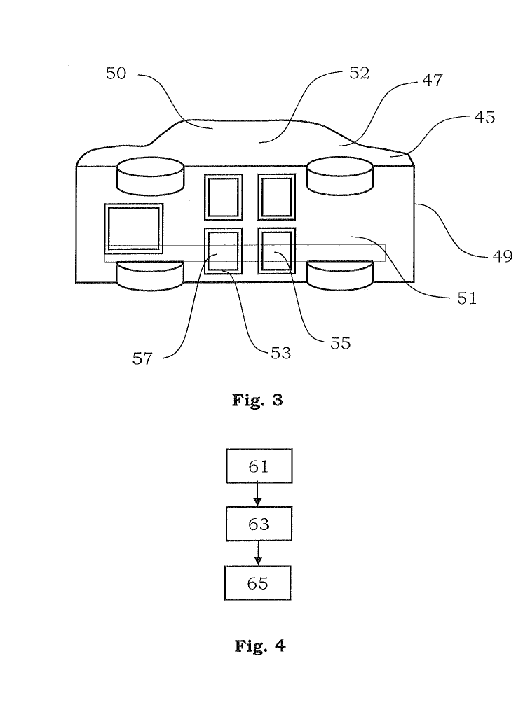

In FIG. 3 a view from below of another example of a vehicle 45 according to the invention is shown. The vehicle 45 comprises a bodywork 47 and a frame 49 having an underside 51. The vehicle further comprises a passenger compartment 50 having sidewalls 52 and a floor portion. The underside of the vehicle further comprises a plurality of mounting spaces 53 opening at the underside of the vehicle and each being designed to accommodate a battery pack 55. During manufacturing of the vehicle the battery packs 55 may be assembled in their own production line, and then be inserted into the mounting space.

In this example, the battery packs 55 comprise an underside surface 57 which is arranged to be flush with the underside 51 of the vehicle. Hence the battery packs 55 and the underside of the vehicle jointly forms a substantially planar downward facing surface. The planar downward facing surface is in this example shaped so that the difference in height between two adjacent sections of the surface differ with less than or equal to 7.5 cm, preferably with less than or equal to 5 cm, more preferably with less than or equal to 2.5 cm, and most preferably with less than or equal to 0.5 cm.

In this example the vehicle comprises four separate battery packs located underneath the passenger compartment 50 and one separate battery pack located underneath the frontal engine compartment. By providing a heavy battery pack at the front, but no battery packs towards the back of the vehicle, the road properties of the vehicle are improved since the centre of gravity is located more to the front of the vehicle.

Furthermore, the battery packs 55 may be detachable from the mounting spaces 53, wherein it is easy to replace one or more of the battery packs provided on the underside. Hence, in case one or more of the battery packs become depleted, the battery pack may be detached and replaced by a new, fully charged battery pack. This provides a method for fast and easy refill of the vehicle with new electric energy. By providing at least two separate battery packs each separate battery pack will also be lighter and can be detached, handled and replaced more easily.

In FIG. 4 a method for providing a battery pack comprising at least one battery cell to an electric motor driven vehicle is shown. The electric motor driven vehicle comprises an underside, and at least one electric motor for propulsion of the vehicle, wherein the electric motor is designed to receive electric energy from the at least one battery pack for propulsion of the vehicle.

In a first, optional, step 61 the method comprises removing a first battery pack having a low state of charge from the underside of the vehicle. The low state of charge may be due to prior use of the vehicle, so that the first battery pack has become depleted, or nearly depleted.

In a second step 63 the method comprises attaching at least one second battery pack in connection with the underside of the vehicle. Preferably the battery pack is attached so that at least a portion of the battery pack containing at least one battery cell is positioned underneath a lower floor portion of a passenger compartment designed for accommodating living beings. Preferably the method also comprises attaching at least one plate-shaped battery pack in connection with the underside of the vehicle.

Preferably, the second battery pack has a higher state of charge than the first battery pack, and is attached so as to replace the first battery pack. By replacing the first battery pack with a second battery pack having a higher state of charge the energy level in the vehicle can be replenished in a fast and reliable manner.

In a third step 65 the method comprises recharging a third, permanent battery pack associated with the vehicle with energy from the second battery pack. Hence a depleted, or nearly depleted, non-replaceable battery pack, for example located in the engine compartment of the vehicle, may be replenished with energy from a replaceable and more easily accessible battery pack on the underside of the vehicle. Hence there is less need for long charging times during which the vehicle needs to be stationary.

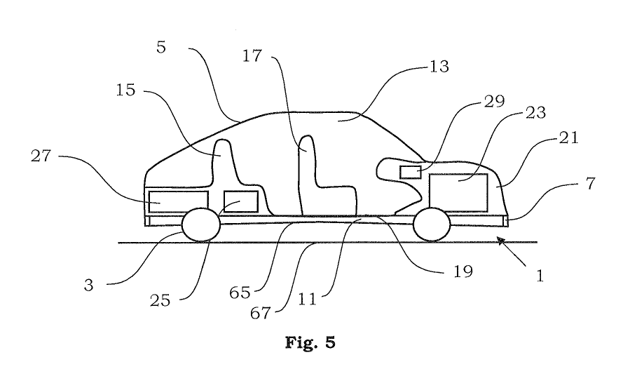

In FIG. 5 yet another example of a vehicle according to the invention is shown. The vehicle 1 is mostly similar to the vehicle described in FIG. 1, and therefore the same reference numbers and designations are used also in relation to FIG. 5.

The vehicle in FIG. 5 comprises an underside surface 65 facing the road 67, which is convex shaped. Hence the height of the surface 65 above the road 67 differs at different positions, creating a channel beneath the vehicle having a differing cross-sectional area. When the vehicle is in motion an airstream is created which flows inside the channel beneath the vehicle, and, due to the increasing cross-section area in the channel, the airstream will experience a decreased air pressure under the vehicle. The decreased air pressure will in turn generate a sucking force in cooperation with an airstream above the vehicle, which aids in pressing the vehicle towards the road. The increase force pressing the vehicle towards the road gives rise to better road holding properties for the vehicle.

The invention is not limited to the embodiments and examples shown, but may be varied freely within the framework of the following claims. In particular, the different features shown in the examples and embodiments may be freely interchanged and/or combined to form new examples and embodiments.

1. A battery pack (11, 35a, 35b, 55) comprising at least one battery cell (39a, 39b), the battery pack being designed to be mounted in an electric vehicle, and to provide electric energy to an electric motor arranged in the vehicle for propulsion of the vehicle, characterized in that the battery pack (11, 35a, 35b, 55) is designed so that at least a part of the battery pack, which part contains at least one battery cell, is mountable underneath a lower floor portion (19) of a passenger compartment of the vehicle.

2. A battery pack according to claim 1, characterized in that the part of the battery pack (11, 35a, 35b, 55) mountable underneath the lower floor portion (19) of the passenger compartment and containing at least one battery cell has a maximum thickness, as measured in the vertical direction when mounted, which is less than or equal to 18 cm.

3. A battery pack according to claim 1, characterized in that the part of the battery pack containing at least one battery cell is designed to occupy at least 50% of the area underneath the lower floor portion of the passenger compartment.

4. A battery pack according to claim 1, characterized in that the part of the battery pack containing the at least one battery cell comprises a housing (37a, 37b) forming part of a frame (7) for the vehicle.

5. A battery pack according to claim 1, characterized in that the battery pack (11, 35a, 35b, 55) is detachable from underneath the vehicle.

6. A battery pack according to claim 5, characterized in that the battery pack (11, 35a, 35b, 55) is designed to be automatically and easily replaceable with another, similar battery pack.

7. A battery pack according to claim 7, characterized in that the battery pack (11) is designed to provide energy to recharge a permanent battery pack (23, 25, 27) in the vehicle.

8. An electric motor driven vehicle comprising a passenger compartment (13) for accommodating living beings, at least one battery pack (11, 35a, 35b, 55) comprising at least one battery cell, and at least one electric motor for propulsion of the vehicle, wherein the electric motor is designed to receive electric energy from the at least one battery pack, characterized in that at least a part of the at least one battery pack, which part contains at least one battery cell, is mounted underneath a lower floor portion (19) of the passenger compartment.

9. An electric motor driven vehicle according to claim 8, characterized in that the parts of the battery pack or packs (11, 35a, 35b, 55) mounted underneath the lower floor portion of the passenger compartment and containing at least one battery cell has a maximum thickness, as measured in a vertical direction, which is less than or equal to 18 cm.

10. An electric motor driven vehicle according to claim 8, characterized in that the vehicle comprises a battery pack or battery packs (11, 35a, 35b, 55) having a part or parts containing battery cells that occupies at least 50% of the area of the floor portion of the passenger compartment.

11. An electric motor driven vehicle according to claim 8, characterized in that the vehicle comprises a frame (7) supporting the vehicle, and that the battery pack (11) comprises a housing (37a, 37b) forming part of the vehicle's frame (7).

12. An electric motor driven vehicle according to claim 8, characterized in that the at least one battery pack (11, 35a, 35b, 55) mounted underneath a lower floor portion of the passenger compartment is easily detachable from the vehicle.

13. An electric motor driven vehicle according to claim 12, characterized in that the at least one battery pack (11, 35a, 35b, 55) mounted underneath a lower floor portion (19) of the passenger compartment is replaceable with another, similar battery pack.

14. An electric motor driven vehicle according to claim 10, characterized in that the vehicle comprises at least one permanent battery pack (23, 25, 27) and a battery charger (29) arranged to recharge the permanent battery pack by transferring energy to the permanent battery pack from the replaceable battery pack (11).

15. An electric motor driven vehicle according to claim 10, characterized in that the vehicle is a land-based, road-bound vehicle comprising an underside facing towards the road which is convex shaped.

16. An electric motor driven vehicle comprising an underside, at least one battery pack (11, 35a, 35b, 55) comprising at least one battery cell, and at least one electric motor for propulsion of the vehicle, wherein the electric motor is designed to receive electric energy from the at least one battery pack for propulsion of the vehicle, characterized in that the vehicle comprises a passenger compartment (13) for accommodating living beings, and that the vehicle comprises a mounting space (53) underneath a lower floor portion of the passenger compartment adapted for mounting at least a part of the at least one battery pack containing at least one battery cell in the mounting space.

17. A method of providing a battery pack comprising at least one battery cell to an electric motor driven vehicle comprising an underside, and at least one electric motor for propulsion of the vehicle, wherein the electric motor is designed to receive electric energy from the at least one battery pack for propulsion of the vehicle, the method comprising
attaching at least one battery pack in connection with the underside of the vehicle, so that at least a portion of the battery pack containing at least a part of one battery cell is positioned underneath a lower floor portion of a passenger compartment designed for accommodating living beings.

18. A method according to claim 17, characterized in that the method comprises
attaching at least one plate-shaped battery pack comprising a flat topside in connection with the underside of the vehicle.

19. A method according to claim 17, characterized in that the method comprises
removing a first battery pack having a low state of charge from the underside of the vehicle, and
attaching a second battery pack having a higher state of charge in connection with the underside of the vehicle to replace the first battery pack.

20. A method according to claim 19, characterized in that the method comprises
recharging a permanent battery pack associated with the vehicle with energy from the second battery pack.
